(19) United States
(12) Patent Application Publication
(10) Pub. No.: US 2005/0174856 A1
(43) Pub. Date: Aug. 11, 2005

(54) Program correction methods and devices using the same

(76) Inventors: Yao-Chieh Cheng, Hsinchu City (TW); Wei-Chung Shih, Taoyuan City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 11/046,935

(22) Filed: Jan. 31, 2005

(30) Foreign Application Priority Data
Feb. 11, 2004 (TW) 93103153

(51) Int. Cl. G11C 11/34

(52) U.S. Cl. 365/185.33

(57) ABSTRACT

A program correction method. A program-driven electronic device for implementing the program correction method contains an erasable memory storing a program comprising to-be-replaced codes need to be replaced stored in a first section. First, updated codes for replacing the to-be-replaced codes are acquired. Next, the updated codes are stored in a second section of the erasable memory. An initial instruction of the to-be-replaced codes is amended to be an exception-causing code which generates a corresponding code-replacement exception when executed. The updated codes are executed when the corresponding code-replacement exception is received.

### BACKGROUND

The invention relates to computer techniques, and in particular to error correction methods and devices utilizing the same.

When to-be-replaced codes exist in a program stored in an erasable memory of a program-driven device, or the program requires updating, the program may be rewritten by loading a correct or a new version of the program. This method is inefficient when the entire update process is carried out to update only a portion of the program. Typically, a user of the device will be instructed to complete the entire update process, which may be inconvenient for the user.

In another method, only the portion of a program in error is replaced by correction code. This method, however, is not always feasible, for example, when the size of correction codes is larger than that of the to-be-replaced codes. If a flash memory storing an operating system of a mobile communication device or a digital camera comprises a codes requiring update or correction, all the codes within a block of the flash memory must be updated. This method also inefficient requires replacement of more than just the code with errors.

Hence, there is a need for a program correction method ameliorating the described disadvantage.

### SUMMARY

Accordingly, the program correction methods and electronic devices using the same are provided. An exemplary embodiment of the program-driven electronic device for implementing the program correction method comprises an erasable memory storing a program wherein a to-be-replaced codes requiring replacement are stored in a first section. First, updated codes for replacing the to-be-replaced codes are acquired. Next, the updated codes are stored in a second section of the erasable memory. An initial instruction of the to-be-replaced codes is amended to be an exception-causing code which, when executed, generates a corresponding code-replacement exception. The updated codes are executed when the corresponding code-replacement exception is received.

The program correction method can be implemented by a computer program stored in a storage medium. The computer program, when executed in a computing device, such as a mobile communication device, directs the computing device to perform the program correction method.

Additionally, an exemplary embodiment of the program-driven electronic device for executing a program correction method comprises an erasable memory and a processing unit. The erasable memory stores a program comprising to-be-replaced codes requiring replacement in a first section thereof. The processing unit is coupled to the erasable memory. When receiving first updated codes for replacing the to-be-replaced codes, the processing unit stores the first updated codes in a second section of the erasable memory. The processing unit amends an initial instruction of the to-be-replaced codes to an exception-causing code which, when executed, generates a corresponding code-replacement exception. The processing unit executes the first updated code when receiving the corresponding code-replacement exception.

### DESCRIPTION OF THE DRAWINGS

The invention can be more fully understood by reading the subsequent detailed description and examples with references made to the accompanying drawings, wherein:

FIG. 1 is a block diagram of the configuration of an exemplary embodiment of a mobile communication device;

FIG. 2 is a schematic diagram of a memory;

FIGS. 3A and 3B are flowcharts of an exemplary embodiment of the program correction method;

FIG. 4 is a schematic diagram of a plurality of updated code sections; and

FIG. 5 is a schematic diagram of an exemplary embodiment of a storage medium.

### DETAILED DESCRIPTION

The program correction methods are provided.

A mobile device is illustrated as an exemplary device implementing the program correction method. The method can be implemented in any program-driven electronic device.

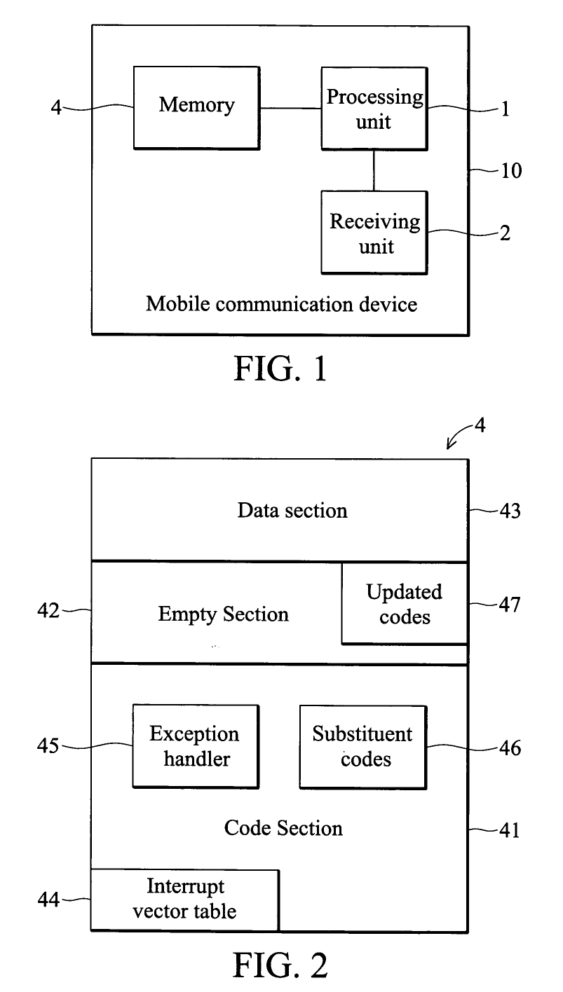

FIG. 1 is a block diagram of the configuration of a mobile communication device 10. Mobile communication device 10 comprises processing unit 1, receiving unit 2 and memory 4. Processing unit 1 couples with receiving unit 2 and memory 4. Receiving unit 2 acquires updated codes.

Receiving unit 2 acquires updated codes from personal computers or the Internet via wireless communication. For example, receiving unit 2 receives Short Messaging Services (SMS) messages to acquire updated codes comprised therein.

Hardware manufacturers typically divide a memory of an electronic device into a data section for storing data and a code section for storing firmware, typically comprising a file system. Not knowing the actual size of the firmware, hardware manufacturers typically allocate greater memory capacity for the code than for the firmware. Hence, an unused section, hereafter referred as empty section, remains after the firmware is loaded into a code section.

FIG. 2 is a schematic diagram of memory 4. Data section 43 is an example of the above-described data section. Code section 41 and empty section 42 comprise an example of the above-described code section.

Code section 41 stores a program for driving the mobile communication device 10. When the program comprises a codes which will be replaced, hereafter referred to as substituent codes, the substituent codes can be updated using the program correction method. Code section 41 comprises substituent codes 46, exception handler 45 and interrupt vector table 44.

In the embodiment, addresses stored in the interrupt vector table 44 all point to the address of exception handler 45. Hence, when an exception occurs, processing unit 1 handles the exceptions according to procedures recorded in exception handler 45.

Different from conventional exception handlers, according to the procedure of the exception handler 45, processing unit 1 first determines whether exceptions received by itself are code-replacement exceptions.

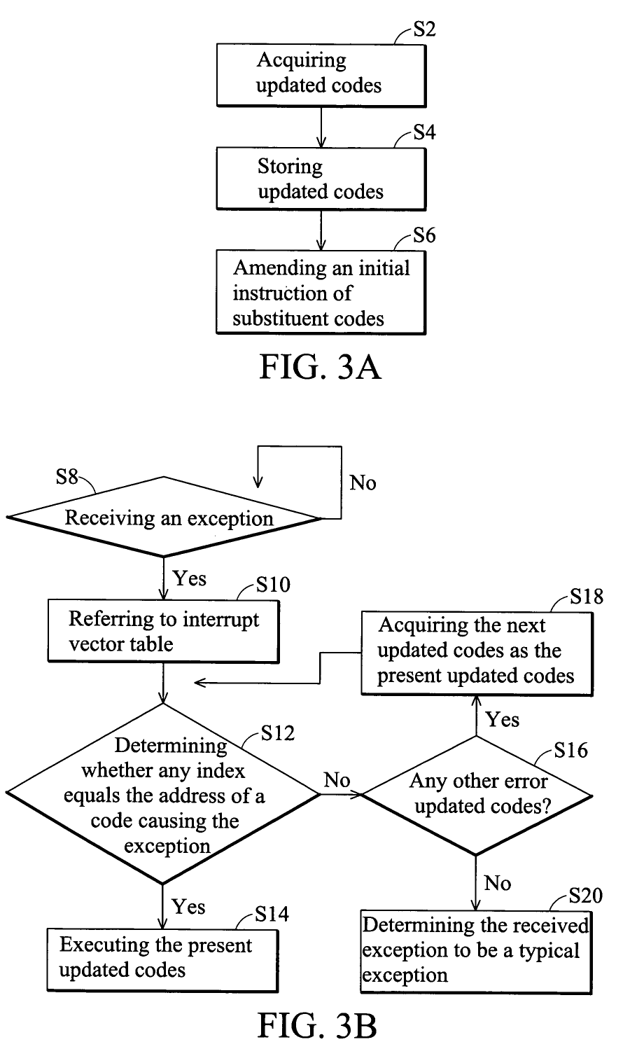

FIG. 3A is a flowchart of an exemplary embodiment of the program correction method. First, processing unit 1 acquires updated codes 47 through receiving unit 2 (step S2), for replacement of substutient codes 46. For example, the manufacturer of mobile communication device 10 sends a short message comprising updated codes 47 to mobile communication device 10. Receiving unit 2 acquires the short message and extracts updated codes 47 thereof.

Next, processing unit 1 stores updated codes 47 in a section within empty section 42 and adjacent to data section 43 typically comprising a file system (step S4). Processing unit 1 records the address of updated codes 47.

After updated codes 47 are stored in memory 4, processing unit 1 amends substituent codes 46 (step S6) to assure generation of code-replacement exceptions whenever processing unit 1 executes substituent codes 46. Thus, processing unit 1 will not execute whole substituent codes 46. Instead, processing unit 1 jumps to the address of updated codes 47 for execution thereof.

Processing unit 1 amends an initial instruction of substituent codes 46 to an exception-causing code which will trigger corresponding code-replacement exceptions when executed by processing unit 1. Exception-causing codes may comprise those with an undefined op code or those accessing illegal memory addresses.

The initial instruction is the first instruction of substituent codes 46. The range of substituent codes 46 can be determined by a designer of updated codes 47. For example, if third to sixth instructions of the firmware in code section 41 require update or comprise to-be-replaced codes, substituent codes 46 may be defined as a range from the third to sixth instructions, a range from second to sixth instructions or any range comprising the third to sixth instructions. As the first instruction of substituent codes 46, the initial instruction may be the third instruction or any instruction before the third instruction. Similarly, if an i-th instruction of the firmware requires update or comprises an error code, the initial instruction may be the i-th instruction or any instruction before the i-th instruction.

In flash memory, if a bit therein is required to be changed from logic “0” to logic “1”, an entire memory block must be erased. All bits within the memory block, therefore, must be rewritten to achieve a bit change from logic “0” to logic “1”. In the exemplary amendment step, therefore, bits are amended from logic “1” to logic “0” rather than from logic “0” to logic “1”. The initial instruction is amended to exception-causing code in the way described above. Thus, only a portion of the memory block comprising substituent codes 46 must be erased.

Processing unit 1 amends the initial instruction to be an exception-causing code according to code-amending data. The code-amending data provides required amendments for the initial instruction and substituent codes 46. For example, the code-amending data comprises data indicating start and end addresses of substituent codes 46 and bits of the initial instruction that will be inverted from logic “1” to logic “0”. The code-amending data may be recorded in the short message or a header of updated codes 47.

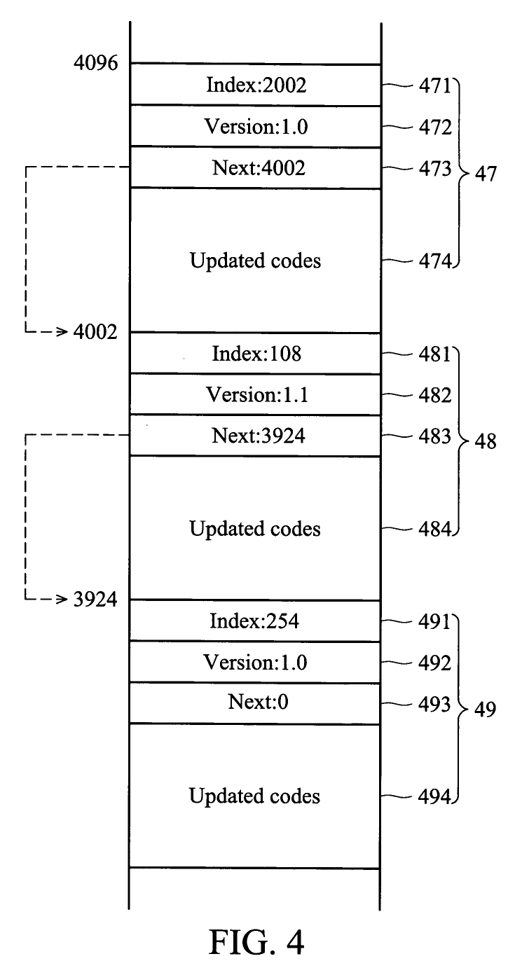

FIG. 4 is a schematic diagram of a plurality of updated code sections. Updated codes 47 comprise a header recording an index, the address of the next updated codes, and the version of updated codes 47. The index comprises the address of the initial instruction of substituent codes 46 corresponding to updated codes 47. If a second updated codes exists, the header thereof further records the address of the initial instruction of corresponding substituent codes. If a third updated codes exists, the header thereof further records the address of the initial instruction of corresponding substituent codes.

For example, fields 471-474 comprise updated codes 47. Field 481-484 comprise updated codes 48. Field 491-494 comprise updated codes 49. The address of the header of updated codes 47 is “4096” which is measured in bytes. The address of the header of updated codes 48 is “4002”. The address of the header of updated codes 49 is “3924”. The next-field 473 in the header of updated codes 47 records “4002”. The next-field 483 in the header of updated codes 48 records “3924”. The next-field 493 in the header of updated codes 49 records “NULL”. The dotted line in FIG. 4 represents the correspondence of the next-field of updated codes and the address of the next group of updated codes.

For example, the address of the initial instruction of substituent codes 46 is “2002”. Hence, index field 471 in the header of updated codes 47 records “2002”. The index field 481 in the header of updated codes 48 records “108” representing the address of the initial instruction of substituent codes corresponding thereto. The index field 491 in the header of updated codes 49 records “254” representing the address of the initial instruction of substituent codes corresponding thereto. Version information recorded in version fields can be referred to for version comparison.

FIG. 3B is a flowchart of the process after the amendment step of the program correction method. Processing unit 1 detects exceptions (step S8). When receiving an exception, processing unit 1 acquires the address of exception handler 45 by referring to interrupt vector table 44 (step S10). Processing unit 1 acquires the address of a code causing the exception according to exception handler 45. Processing unit 1 acquires the indices from headers of updated codes 47˜49, comprising the addresses of the initial instructions of substituent codes. For example, processing unit 1 acquires headers of updated codes 47˜49 and indices therein by referring to the next-field thereof. Processing unit 1 determines whether any of the indices equals the address of the code causing the exception (step S12).

If the index of updated codes 47 equals the address of the code causing the exception, processing unit 1 determines the received exception as a code-replacement exception. In other words, the received exception is a code-replacement exception caused by executing the initial instruction of substituent codes 46. For example, the address of a code causing the exception received by processing unit 1 is equal to index value “2002” of updated codes 47, processing unit 1 determines that the received exception is a code-replacement exception caused by executing the initial instruction of substituent codes 46. Additionally, updated codes 47 are determined to be the updated codes for replacing substituent codes 46. Hence, processing unit 1 then executes updated codes 47 instead of substituent codes 46 (step S14).

The updated codes comprise information for returning to certain codes stored in firmware. Hence, if necessary, processing unit 1 can return to execute the codes stored in firmware.

If the index of updated codes 47 differs from the address of the code causing the exception, the received exception is determined to be an exception other than a code-replacement exception for triggering execution of the present updated codes. Processing unit 1 determines if the address of any next updated codes is recorded in the header of the present updated codes (Step S16). If so, processing unit 1 acquires the next updated codes as the present updated codes according to the address recorded in the “next” field (step S18). Next, processing unit 1 repeats step S12. For example, if “254” is the address of a code causing the exception received by the processing unit 1, processing unit 1 sequentially compares whether the index of headers of updated codes 48˜49 is equal to “254”. Processing unit 1 then executes a corresponding updated codes based on the comparison.

When the address of the next updated codes is not recorded in the present updated codes, the received exception is determined to be an exception other than a code-replacement exception (step S20). Next, when a typical exception occurs, processing unit 1 acquires the exception handler corresponding to the received exception and handles the received exception accordingly. For example, if “235” is the address of a code causing the exception received by the processing unit 1, processing unit 1 sequentially compares whether indices in headers of updated codes 47˜49 are equal to “235”. When no index field with “235” is located after searching all sections of updated codes, and the last updated codes does not comprise the address of any next updated codes, processing unit 1 determines the received exception to be a general exception. The received exception is handled as a typical exception.

Empty section 42 is an unused portion of the code section, of which capacity may be typically up to hundreds of kilobytes. Hence, it is more efficient to make good use of empty section 42 by storing updated codes therein. In addition, because the address of the byte adjacent to data section 43 is easily obtained, updated codes are preferably stored in a section adjacent thereto. Updated codes, however, may be stored directly in data section 43 or in another section of memory 4.

The step of amending the initial instruction of the to-be-replaced codes is implemented by replacing some logic “1” bits with logic “0” bits. Even if stored in a flash memory, the initial instruction can be amended without erasing an entire block of flash memory.

When the mobile communication device 10 is a mobile phone, the mobile communication device 10 can receive updated codes via a short message. The arrangement, however, is not intended to limit the invention. The updated codes can be obtained by other methods.

Additionally, the program correction method can be implemented in a computer program stored in a storage medium, such as memory 4. The computer program, when executed in a computing device, such as mobile communication device 10, directs the computing device to perform the program correction method.

Hence, the present invention provides a storage medium storing a computer program for implementing the program correction method.

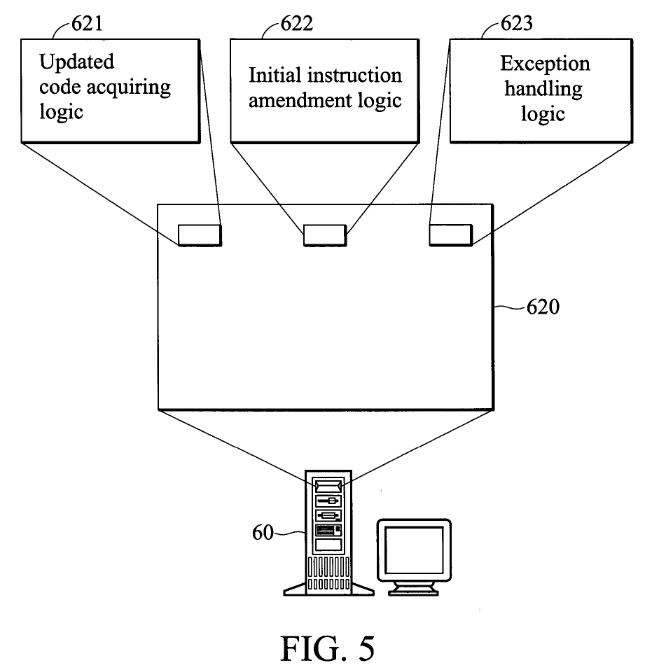

FIG. 5 is a schematic diagram of the storage medium. Storage medium 60 stores computer program 620 for implementing the program correction method. Computer program 620 comprises updated code receiving logic 621, initial instruction amendment logic 622 and exception handling logic 623.

Updated code receiving logic 621 acquires and stores updated codes in a memory. The initial instruction amendment logic 622 amends an initial instruction of to-be-replaced codes to an exception-causing code. Exception handling logic 623 determines code-replacement exceptions and executes corresponding updated codes.

Hence, the program correction method of the invention is capable of ameliorating the described disadvantage of conventional method.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A program correction method performed in a program-driven electronic device comprising an erasable memory storing a program comprising to-be-replaced codes need to be replaced and stored in a first section thereof, comprising the steps of:
receiving first updated codes for replacing the to-be-replaced codes;
storing the first updated codes in a second section of the erasable memory;
amending an initial instruction of the to-be-replaced codes to an exception-causing code which generates a corresponding code-replacement exception when executed; and
executing the first updated code when the corresponding code-replacement exception is received.

2. The method as claimed in claim 1, wherein the second section comprises an empty section in the erasable memory.

3. The method as claimed in claim 1, wherein the second section comprises an empty section in the erasable memory, adjacent to a data section thereof.

4. The method as claimed in claim 1, further comprising the step of receiving an exception caused by a first code.

5. The method as claimed in claim 4, further comprising the step of accessing an exception handler by referring to an interrupt vector table, wherein the exception handler is responsible for determining whether the received exception comprises the code-replacement exception.

6. The method as claimed in claim 4, further comprising the step of comparing the address of the first code to an index of the first updated codes to determine whether the received exception comprises the code-replacement exception, wherein the index records the address of the initial instruction of the to-be-replaced codes.

7. The method as claimed in claim 6, wherein another second updated codes are stored in the second section, and the method further comprises the step of receiving the second updated codes according to the address thereof recorded in a header of the first updated codes.

8. The method as claimed in claim 1, wherein the amendment step is implemented by the step of replacing specified bits of logic 1 by bits of logic 0.

9. The method as claimed in claim 1, wherein the first updated codes is acquired by the step of receiving a short message conforming to short messaging services protocol.

10. A program-driven electronic device for executing a program correction method, comprising:
an erasable memory for storing a program comprising to-be-replaced codes need to be replaced in a first section thereof; and
a processing unit coupled to the erasable memory, wherein the processing unit, when receiving first updated codes for replacing the to-be-replaced codes, stores the first updated codes in a second section of the erasable memory; the processing unit amends an initial instruction of the to-be-replaced codes to an exception-causing code which generates a corresponding code-replacement exception when executed, and executes the first updated code when receiving the corresponding code-replacement exception.

11. The device as claimed in claim 10, wherein the second section comprises an empty section in the erasable memory.

12. The device as claimed in claim 10, wherein the second section comprises an empty section in the erasable memory, adjacent to a data section thereof.

13. The device as claimed in claim 10, wherein the processing unit further receives an exception caused by a first code.

14. The device as claimed in claim 13, the processing unit further accesses an exception handler by referring to an interrupt vector table, wherein the exception handler is responsible for determining whether the received exception comprises the code-replacement exception.

15. The device as claimed in claim 13, wherein the processing unit, after receiving the exception, further compares the address of the first code to an index of the first updated codes to determine whether the received exception comprises the code-replacement exception, wherein the index records the address of the initial instruction of the to-be-replaced codes.

16. The device as claimed in claim 15, wherein another second updated codes are stored in the second section, and the processing unit further acquires the second updated codes according to the address thereof recorded in a header of the first updated codes.

17. The device as claimed in claim 10, wherein the processing unit amends the initial instruction by replacing specified bits of logic 1 by bits of logic 0.

18. The device as claimed in claim 10, wherein the program-driven electronic device comprises a mobile communication device.

19. The device as claimed in claim 18, wherein the processing unit acquires the first updated codes by receiving a short message conforming to short messaging services protocol.

20. A machine-readable storage medium storing a computer program which, when executed in a program-driven electronic device comprising an erasable memory storing a program comprising to-be-replaced codes need to be replaced in a first section thereof, directs the program-driven electronic device to perform a program correction method comprising:
receiving first updated codes for replacing the to-be-replaced codes;
storing the first updated codes in a second section of the erasable memory;
amending an initial instruction of the to-be-replaced codes to an exception-causing code which generates a corresponding code-replacement exception when executed; and
executing the first updated code when the corresponding code-replacement exception is received.
